(19) United States
(12) Patent Application Publication
(10) Pub. No.: US 2019/0355762 A1
(43) Pub. Date: Nov. 21, 2019

(54) FLEXIBLE DISPLAY PANELS AND FLEXIBLE DISPLAY DEVICES

(71) Applicant: KunShan Go-Visionox Opto-Electronics Co., Ltd., Kunshan (CN)

(72) Inventors: Gang WANG, Kunshan (CN); Lu ZHANG, Kunshan (CN); Zhenzhen HAN, Kunshan (CN); Siming HU, Kunshan (CN); Hui ZHU, Kunshan (CN)

(21) Appl. No.: 16/530,215

(22) Filed: Aug. 2, 2019

Related U.S. Application Data
(63) Continuation of application No. PCT/CN2018/090261, filed on Jun. 7, 2018.

(30) Foreign Application Priority Data
Aug. 31, 2017 (CN) 201721111018.4

(51) Int. Cl. H01L 27/12

(52) U.S. Cl. CPC H01L 27/1244; H01L 27/3276

(57) ABSTRACT

A flexible display panel and a flexible display device are provided according to exemplary embodiments of the present application. The flexible display panel includes a plurality of pixel units. Two adjacent pixel units are electrically connected by a connection line structure, and the connection line structure includes a first trace layer adopting a flexible conductive material; and a second trace layer located in a different layer from the first trace layer. The first trace layer is electrically connected to the second trace layer.

### CROSS-REFERENCE TO RELATED APPLICATIONS

This application is a continuation of International Application No. PCT/CN2018/090261 filed on Jun. 7, 2018, which claims priority to Chinese patent application No. 201721111018.4 filed on Aug. 31, 2017. Both applications are incorporated herein by reference in their entireties.

### TECHNICAL FIELD

Exemplary embodiments of the present application relate to the field of display device technologies.

### BACKGROUND

A flexible display panel refers to a display panel which is bendable and deformable, and includes various types such as a flexible Organic Electroluminescence Display Diode (OLED), a flexible Electrophoretic Display Device (EPD), and a flexible Liquid Crystal Display Device (LCD). The bendable and deformable flexible display panel can provide a disruptive experience for users.

### SUMMARY

Exemplary embodiments of the present application provide a flexible display panel and a flexible display device, which solve a problem that a connection line structure between two adjacent pixel units of a flexible display panel is prone to fracture.

A flexible display panel according to an exemplary embodiment of the present application includes a plurality of pixel units. Two adjacent pixel units are electrically connected by a connection line structure. The connection line structure includes a first trace layer adopting a flexible conductive material; and a second trace layer located in a different layer from the first trace layer. The first trace layer is electrically connected to the second trace layer.

In an exemplary embodiment, the first trace layer and a source and a drain of each of the plurality of pixel units are in a same layer in a vertical direction.

In an exemplary embodiment, the first trace layer comprises a laminated composite structure.

In an exemplary embodiment, the first trace layer includes a first titanium metal layer, an aluminum metal layer and a second titanium metal layer; and the aluminum metal layer is sandwiched between the first titanium metal layer and the second titanium metal layer.

In an exemplary embodiment, the first trace layer and the second trace layer are electrically connected by at least a via hole disposed in the vertical direction, and the via hole is filled with a conductive material.

In an exemplary embodiment, the conductive material filled in the via hole adopts a material same as that of the first trace layer.

In an exemplary embodiment, the first trace layer or the second trace layer is provided with at least one opening, or each of the first trace layer and the second trace layer is provided with at least one opening.

In an exemplary embodiment, a material of the second trace layer is polysilicon.

In an exemplary embodiment, the connection line structure includes a substrate; a buffer layer disposed on the substrate; and at least one insulating layer formed on the second trace layer; wherein, the second trace layer is formed on the buffer layer; and the first trace layer is formed on the at least one insulating layer.

An exemplary embodiment of the present application further provides a flexible display device comprising the flexible display panel according to any one of the preceding exemplary embodiments.

The connection line structure of the flexible display device according to the exemplary embodiments of the present application includes the first trace layer and the second trace layer which may be located in different layers and electrically connected, and the first trace layer is made of the flexible conductive material. Thus, comparing with a structure that the adjacent pixel units are electrically connected only by the second trace layer, when the flexible display panel is deformed or bent, the first trace layer of the connection line structure can alleviate a stress concentration caused by the deformation or bending of the flexible display panel, thereby increasing an overall bending resistance performance of the connection line structure and reducing a risk of fracture failure of the flexible display panel.

### BRIEF DESCRIPTION OF DRAWINGS

FIG. 1 is a schematic diagram of a connection structure of pixel units in a flexible display panel.

FIG. 2 is a schematic diagram of a flat layout of a flexible display panel according to an exemplary embodiment of the present application.

FIG. 3 is a schematic cross-sectional diagram of the flexible display panel acquired along line A-A shown in FIG. 2 according to an exemplary embodiment of the present application.

FIG. 4 is a schematic cross-sectional diagram of a flexible display panel according to an exemplary embodiment of the present application.

FIG. 5 is a schematic diagram of a first trace layer or a second trace layer according to an exemplary embodiment of the present application.

### DETAILED DESCRIPTION

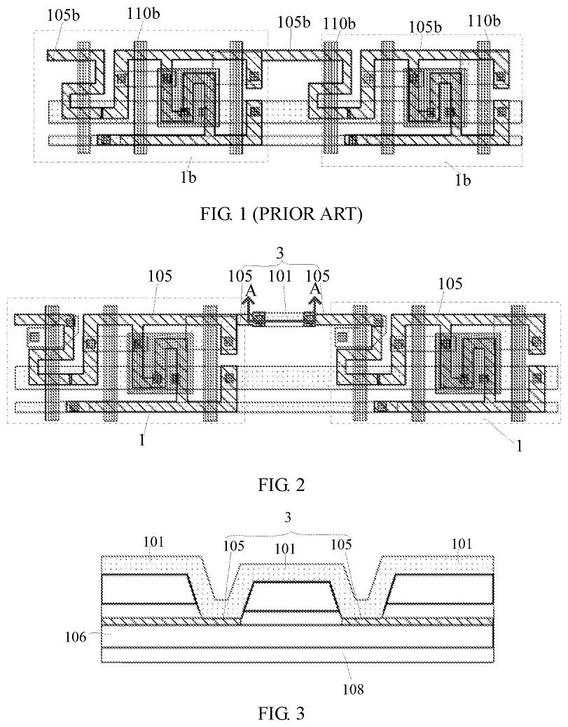

As shown in FIG. 1, the adjacent pixel units 1b of a conventional flexible display panel are electrically connected by a second trace layer 105b. however, when the flexible display panel is in a process of bending or folding, the second trace layer 105b in a transition region between the adjacent pixel units is prone to crack or even fracture, thereby resulting in the flexible display panel not working properly or affecting a display effect.

The technical solutions in the exemplary embodiments of the present application are clearly and completely described in the following with reference to the accompanying drawings in the exemplary embodiments of the present application. It is obvious that the described exemplary embodiments are only a part of the embodiments of the present application, and not all of the embodiments. All other embodiments obtained by those skilled in the art based on the exemplary embodiments of the present application without creative efforts are within the scope of the present application.

A flexible display device according to an exemplary embodiment of the present application includes two adjacent pixel units 1 and a connection line structure 3, and the two adjacent pixel units 1 are electrically connected by the connection line structure 3. The connection line structure 3 includes a first trace layer 101 adopting a flexible conductive material, and a second trace layer 105 located in a different layer from the first trace layer 101. The first trace layer 101 is electrically connected to the second trace layer 105.

FIG. 2 is a schematic diagram of a flat layout of a flexible display panel according to an exemplary embodiment of the present application. FIG. 3 is a schematic cross-sectional diagram of the flexible display panel acquired along a line A-A shown in FIG. 2 according to an exemplary embodiment of the present application.

As shown in FIG. 2 and FIG. 3, the first trace layer 101 and the second trace layer 105 are electrically connected in a vertical direction and are in different layers in the vertical direction. The vertical direction refers to a direction perpendicular to a surface of the flexible display device.

In an exemplary embodiment of the present application, the first trace layer 101 may be directly prepared on a surface of a bent region of the second trace layer 105 to form the electrical connection between the first trace layer 101 and the second trace layer 105. However, the specific manner of the electrical connection between the first trace layer 101 and the second trace layer 105 is not limited in the exemplary embodiment of the present application.

It should be understood that although only two pixel units 1 are shown in the exemplary embodiment shown in FIG. 2 and FIG. 3, the number of the pixel units 1 may be adjusted according to requirements in a manufacturing process of the flexible display device. The number of the pixel units 1 is not specifically limited in the exemplary embodiment of the present application.

It should be seen that the connection line structure 3 between the adjacent pixel units 1 of the exemplary embodiment of the present application may include a structure that the first trace layer 101 and the second trace layer 105 are located in different layers and electrically connected, and the first trace layer 101 is made of the flexible conductive material. Thus, compared with a structure that the adjacent pixel units 1 are electrically connected only by the second trace layer, the first trace layer 101 increases an overall bending resistance performance of the connection line structure 3. When the flexible display device is deformed or bent, the first trace layer 101 of the connection line structure 3 can alleviate a stress concentration caused by the deformation or bending of the flexible display device, thereby increasing the overall bending resistance performance of the connection line structure and reducing a risk of fracture failure of the flexible display panel.

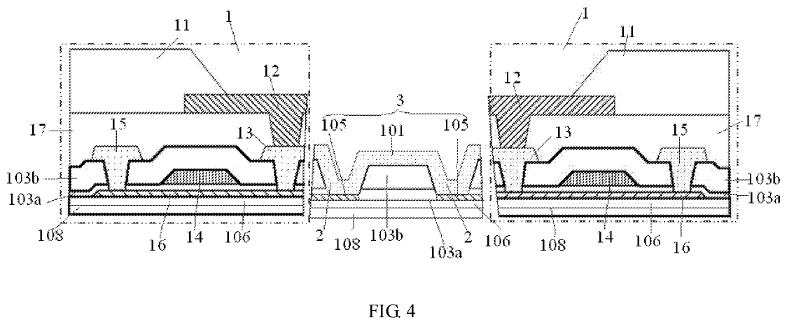

FIG. 4 is a schematic cross-sectional diagram of a flexible display panel according to an exemplary embodiment of the present application. As shown in FIG. 4, the pixel unit 1 may include a substrate 108, a source 15, a drain 13, a gate 14, an anode 12, and a buffer layer 106, an active layer 16, an insulating layer 103, a flat layer 17, and a pixel defining layer 11 sequentially disposed on the substrate 108. It should be understood that, in the exemplary embodiment of the present application, the pixel unit 1 may further include a capacitor electrode located above the gate 14 not shown in FIG. 4.

Specifically, the insulating layer 103 may include a lower insulating layer 103a and an upper insulating layer 103b. The gate 14 is prepared upon the lower insulating layer 103a and covered by the upper insulating layer 103b. The insulating layer 103 may include two openings penetrating the active layer 16. The drain 13 and the source 15 are respectively prepared in the two openings and formed an ohmic contact with the active layer 16 respectively. An anode region is defined on the pixel defining layer 11, and the anode 12 is prepared in the anode region, penetrating the flat layer 17 to form an ohmic contact with the drain 13.

Referring to FIG. 4, in an exemplary embodiment of the present application, the first trace layer 101 may be in a same layer as the source 15 and the drain 13 of the pixel unit 1 in the vertical direction, such that when the first trace layer 101, the source 15 and the drain 13 of the pixel unit 1 are made of a same flexible conductive material, the first trace layer 101, the source 15 and the drain 13 of the pixel unit may be prepared together, instead of preparing the first trace layer 101 separately, thereby simplifying a preparation process of the flexible display panel. However, it should be understood that, in the exemplary embodiment of the present application, FIG. 4 is only an example of an internal structure of the pixel unit 1 in the flexible display panel, and the internal structure of the pixel unit 1 may be adjusted according to an actual application scenario. The internal structure of the pixel unit 1 is not limited in the exemplary embodiment of the present application.

In an exemplary embodiment of the present application, the first trace layer 101 may be a laminated composite structure. For example, the first trace layer 101 may include a titanium-aluminum-titanium laminated composite structure which includes a first titanium metal layer, an aluminum metal layer, and a second titanium metal layer. The aluminum metal layer is sandwiched between the first titanium metal layer and the second titanium metal layer. A yield strength and a tensile strength of the titanium-aluminum-titanium laminated composite structure are relatively good, so that the overall bending resistance performance of a display region can be increased.

Referring to FIG. 4, in an exemplary embodiment of the present application, the first trace layer 101 and the second trace layer 105 are electrically connected by at least one via hole 2 filled with a conductive material disposed in the vertical direction. However, it should be understood that the first trace layer 101 and the second trace layer 105 may also be electrically connected in other manners in the vertical direction. The electrical connection manner of the first trace layer 101 and the second trace layer 105 in the vertical direction is not specifically limited in the exemplary embodiments of the present application.

In an exemplary embodiment of the present application, the via hole 2 is filled with the same conductive material as the first trace layer 101, so that the filling of the via hole 2 may be completed when the first trace layer 101 is prepared, and a step for separately filling the conductive material into the via hole 2 is omitted during a preparation process of the flexible display panel, thereby simplifying the preparation process of the flexible display panel.

In an exemplary embodiment of the present application, the second trace layer 105 may be made of a P-SI (polysilicon) material. However, it should be understood that the second trace layer 105 may also be made of other conductive materials. The material of the second trace layer 105 is not specifically limited in the exemplary embodiments of the present application.

Referring to FIG. 3, in an exemplary embodiment of the present application, the connection line structure 3 in the flexible display panel may include a substrate 108, a buffer layer 106 disposed on the substrate 108, and at least one insulating layer 103 prepared on the second trace layer 105. The second trace layer 105 is prepared on the buffer layer 106, and the first trace layer 101 is prepared on the at least one insulating layer 103.

The substrate 108 refers to a substrate for supporting each element of the pixel unit 1. In an exemplary embodiment of the present application, the substrate 108 may be a flexible substrate. In another exemplary embodiment of the present application, the substrate 108 may also be a glass substrate. The material of the substrate 108 is not specifically limited in the exemplary embodiments of the present application.

The buffer layer 106 may be configured to prevent moisture or impurities from intruding into the pixel unit 1 through the substrate 108, thereby facilitating subsequent fabrication processes. However, the buffer layer 106 may be formed of one or both of a silicon oxide film and a silicon nitride film. The material of the buffer layer 106 is not specifically limited in the exemplary embodiments of the present application. In addition, in an exemplary embodiment of the present application, the buffer layer 106 may not be included, and the second trace layer 105 may be directly formed on the substrate 108.

In an exemplary embodiment of the present application, the at least one insulating layer 103 may include the via hole 2 filled with a conductive material to electrically connect the first trace layer 101 and the second trace layer 105.

In an exemplary embodiment of the present application, referring to FIG. 3 and FIG. 4, a plurality of insulating layers need to be prepared in the pixel unit 1 to isolate a plurality of trace layers. Therefore, in order to simplify the preparation process, the insulating layer 103 in the pixel unit 1 and the insulating layer 103 in the connection line structure between the adjacent pixel units 1 may be simultaneously prepared. However, the number of the insulating layers 103 included in the connection line structure is not limited in the exemplary embodiments of the present application.

It should be understood that in addition to the first trace layer 101 located above the second trace layer 105 as shown in FIG. 3, the second trace layer 105 may also be electrically connected to a layer adopting a flexible conductive material located at other layers to satisfy requirements of the bending resistance performance. The position of the first trace layer 101 in the vertical direction is not specifically limited in the exemplary embodiments of the present application.

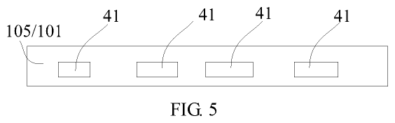

FIG. 5 is a schematic diagram of a first trace layer or a second trace layer according to an exemplary embodiment of the present application.

In the exemplary embodiment of the present application, in order to further improve the bending resistance performance of the first trace layer 101 or the second trace layer 105, as shown in FIG. 5, the first trace layer 101 or the second trace layer 105 according to the exemplary embodiment of the present application may further include at least one opening 41 which can disperse the stress generated when the first trace layer 101 or the second trace layer 105 is bent, thereby further preventing the first trace layer 101 or the second trace layer 105 from being cracked or broken when the flexible display panel is in a process of bending or folding, and improving the quality and reliability of the first trace layer 101 or the second trace layer 105 when bent. It should be understood that, in an exemplary embodiment of the present application, the openings 41 may be disposed on both the first trace layer 101 and the second trace layer 105.

In an exemplary embodiment of the present application, the opening 41 may be quadrilateral, circular or other shape. However, the shape of the opening is not specifically limited in the exemplary embodiments of the present application.

In an exemplary embodiment of the present application, a flexible display device is further provided, which includes the flexible display panel provided in any one of the preceding exemplary embodiments.

In addition, qualifiers such as the first, the second and the third mentioned in the exemplary embodiments of the present application are only used for more clearly describing the technical solutions of the exemplary embodiments of the present application, and are not intended to limit the scope of the present application.

The above are only the preferred exemplary embodiments of the present application, and are not intended to limit the scope of the present application. Any modifications, equivalent replacements, improvements, etc. made within the spirit and principles of the present application should be included within the scope of the present application.

What is claimed is:

1. A flexible display panel, comprising:
a plurality of pixel units, two adjacent pixel units being electrically connected by a connection line structure;
the connection line structure comprising:
a first trace layer adopting a flexible conductive material; and
a second trace layer located in a different layer from the first trace layer and being electrically connected to the first trace layer.

2. The flexible display panel of claim 1, wherein the first trace layer and a source and a drain of each of the plurality of pixel units are in a same layer in a vertical direction.

3. The flexible display panel of claim 1, wherein the first trace layer comprises a laminated composite structure.

4. The flexible display panel of claim 3, wherein the first trace layer comprises a first titanium metal layer, an aluminum metal layer and a second titanium metal layer; and the aluminum metal layer is sandwiched between the first titanium metal layer and the second titanium metal layer.

5. The flexible display panel of claim 1, wherein the first trace layer and the second trace layer are electrically connected by a via hole disposed in the vertical direction, and the via hole is filled with a conductive material.

6. The flexible display panel of claim 5, wherein the conductive material filled in the via hole adopts a material same as that of the first trace layer.

7. The flexible display panel of claim 1, the first trace layer or the second trace layer is provided with at least one opening, or each of the first trace layer and the second trace layer is provided with at least one opening.

8. The flexible display panel of claim 1, wherein a material of the second trace layer is polysilicon.

9. The flexible display panel of claim 1, wherein the connection line structure comprises:
a substrate;
a buffer layer disposed on the substrate; and
at least one insulating layer formed on the second trace layer;
the second trace layer is formed on the buffer layer, and the first trace layer is formed on the at least one insulating layer.

10. A flexible display device, comprising the flexible display panel of claim 1.
